(19) United States
(12) Patent Application Publication
(10) Pub. No.: US 2025/0336813 A1
(43) Pub. Date: Oct. 30, 2025

(54) METHOD OF MANUFACTURING SEMICONDUCTOR DEVICE AND SEMICONDUCTOR DEVICE

(71) Applicant: Renesas Electronics Corporation, Tokyo (JP)

(72) Inventors: Toshiaki MORIOKA, Tokyo (JP); Koichi TAKEDA, Tokyo (JP); Kohei HASHIMOTO, Tokyo (JP); Hiromichi TAKAOKA, Tokyo (JP)

(21) Appl. No.: 19/068,091

(22) Filed: Mar. 3, 2025

(30) Foreign Application Priority Data
Apr. 26, 2024 (JP) 2024-072984

(51) Int. Cl. H01L 23/525; H01L 21/66

(52) U.S. Cl. CPC H01L 23/5256; H01L 22/22

(57) ABSTRACT

The current control circuit switches the cutting control transistor to the on state with respect to the AND circuit, passing a current of a first current value through the electrical fuse, and using the heat generated by passing the first current value through the electrical fuse to start melting the cutting region of the electrical fuse; the current detection circuit detects a second current value that is smaller than the first current value and greater than 0 amperes; the current detection circuit outputs a low current detection signal to the detection signal processing circuit based on detecting the second current value; the detection signal processing circuit outputs a control signal to the AND circuit based on the low current detection signal, and the AND circuit switches the cutting control transistor to the off state based on the control signal, performing the cutting of the electrical fuse.

### CROSS-REFERENCE TO RELATED APPLICATIONS

The disclosure of Japanese Patent Application No. 2024-072984 filed on Apr. 26, 2024, including the specification, drawings and abstract is incorporated herein by reference in its entirety.

### BACKGROUND

The present invention relates to a method for manufacturing a semiconductor device and a semiconductor device, for example, a method for manufacturing a semiconductor device having an electrical fuse and the semiconductor device.

There are disclosed techniques listed below.

### [Patent Document 1] Japanese Unexamined Patent Application Publication No. 2011-222691

### [Patent Document 2] Japanese Unexamined Patent Application Publication No. 2024-15652

There is semiconductor devices equipped with electrical fuses (Patent Document 1 and Patent Document 2). In such semiconductor devices, by cutting the electrical fuse, it is possible to adjust circuit characteristics or eliminate defective circuits. Methods for cutting electrical fuses include irradiating with laser light to melt the fuse or passing a current to melt the fuse using Joule heat.

### SUMMARY

The method of cutting the electrical fuse using Joule heat is performed as follows. First, a high voltage is applied from an external tester to cut the electrical fuse. Then, a clock signal is input from the tester to control the cutting time of the electrical fuse. When the clock signal is activated, current flows through the electrical fuse, and the fuse melts. However, since the control of cutting depends on an external tester, there are cases where cutting defects of the electrical fuse occur due to process variations, etc.

The embodiments described later have been made in view of such circumstances, and other problems and novel features will become apparent from the description and accompanying drawings of this specification.

A method: for manufacturing a semiconductor device according to one embodiment includes a step of electrically cutting a fuse element using a first voltage applied from the outside, and this step includes: (d1) with the first voltage applied to the first terminal of the electrical fuse, the current control circuit switches the first transistor to the on state with respect to the control circuit to allow a current of the first current value to flow through the electrical fuse, and using the heat generated by flowing the current of the first current value through the electrical fuse, initiates melting of the cutting region of the electrical fuse; (d2) after step (d1), the current detection circuit detects a second current value that is smaller than the first current value and greater than 0 amperes; (d3) after step (d2), the current detection circuit outputs a detection signal to the detection signal processing circuit based on detecting the second current value; and (d4) after step (d3), the detection signal processing circuit outputs a control signal to the control circuit based on the detection signal, and the control circuit switches the first transistor to the off state based on the control signal, thereby cutting the electrical fuse.

According to the embodiment, the reliability of the semiconductor device can be improved.

### BRIEF DESCRIPTION OF THE DRAWINGS

FIG. 1 is a block diagram showing a circuit configuration example of a semiconductor device according to the first embodiment.

FIG. 2 is a top view showing a configuration example of an electrical fuse in the semiconductor device of FIG. 1.

FIG. 3 is a cross-sectional view along line A in the electrical fuse of FIG. 2.

FIG. 4 is a top view showing an example of a cutting defect in a conventional electrical fuse.

FIG. 5 is a cross-sectional view along line B in the electrical fuse of FIG. 4.

FIG. 6 is a cross-sectional view along line C in the electrical fuse of FIG. 4.

FIG. 7 is a circuit diagram showing the electrical fuse and the cutting control transistor.

FIG. 8 is a diagram showing an example of the cutting high voltage, the potential on the other terminal side of the electrical fuse, and the change in cutting current in the circuit of FIG. 7.

FIG. 9 is a schematic diagram of the electrical fuse.

FIG. 10 is a diagram showing a state where the first portion of the fuse body of the electrical fuse is melted in FIG. 9.

FIG. 11 is an explanatory diagram showing the remaining region melted by residual heat in the fuse body of the electrical fuse in FIG. 10.

FIG. 12 is a detailed circuit diagram of the semiconductor device of FIG. 1.

FIG. 13 is a timing chart showing the operation of the semiconductor device of FIG. 12.

FIG. 14 is a block diagram showing a circuit configuration example of a semiconductor device according to the second embodiment.

FIG. 15 is a block diagram showing a circuit configuration example of a semiconductor device according to the third embodiment.

FIG. 16 is an explanatory diagram of the problem in the third embodiment.

FIG. 17 is an explanatory diagram of the problem in the third embodiment.

FIG. 18 is a detailed circuit diagram of the semiconductor device of FIG. 15.

FIG. 19 is a timing chart showing the operation of the semiconductor device of FIG. 18.

FIG. 20 is a block diagram showing a circuit configuration example of a semiconductor device according to another embodiment.

FIG. 21 is a flowchart of the method for manufacturing a semiconductor device.

### DETAILED DESCRIPTION

In the following embodiments, for convenience, when necessary, the description is divided into multiple sections or embodiments, but unless specifically stated otherwise, they are not unrelated to each other, and one is related to the other as a part or whole modification, detail, supplementary explanation, etc. Also, in the following embodiments, when referring to the number of elements, etc. (including quantity, numerical value, amount, range, etc.), unless specifically stated otherwise and unless it is clearly limited to a specific number in principle, it is not limited to that specific number, and it may be more or less than that specific number.

Furthermore, in the following embodiments, the components (including element steps, etc.) are not necessarily essential unless specifically stated otherwise and unless it is clearly considered essential in principle. Similarly, in the following embodiments, when referring to the shape, positional relationship, etc. of components, unless specifically stated otherwise and unless it is clearly considered otherwise in principle, it is assumed to include those that are substantially approximate or similar to that shape, etc. The same applies to the above numerical values and ranges.

Also, the circuit elements constituting each functional block of the embodiment are not particularly limited but are formed on a semiconductor substrate such as single crystal silicon by integrated circuit technology such as known CMOS (complementary MOS transistor). In the embodiment, a MOSFET (Metal Oxide Semiconductor Field Effect Transistor) (abbreviated as MOS transistor) is used as an example of a MISFET (Metal Insulator Semiconductor Field Effect Transistor), but it does not exclude non-oxide films as gate insulating films. In the embodiment, a p-channel type MOSFET and an n-channel type MOSFET are referred to as a pMOS transistor and an nMOS transistor, respectively.

Hereinafter, embodiments of the present invention are described in detail with reference to the drawings. In all the drawings for explaining the embodiments, the same reference numerals are given to the same members in principle, and repeated explanations are omitted.

### First Embodiment

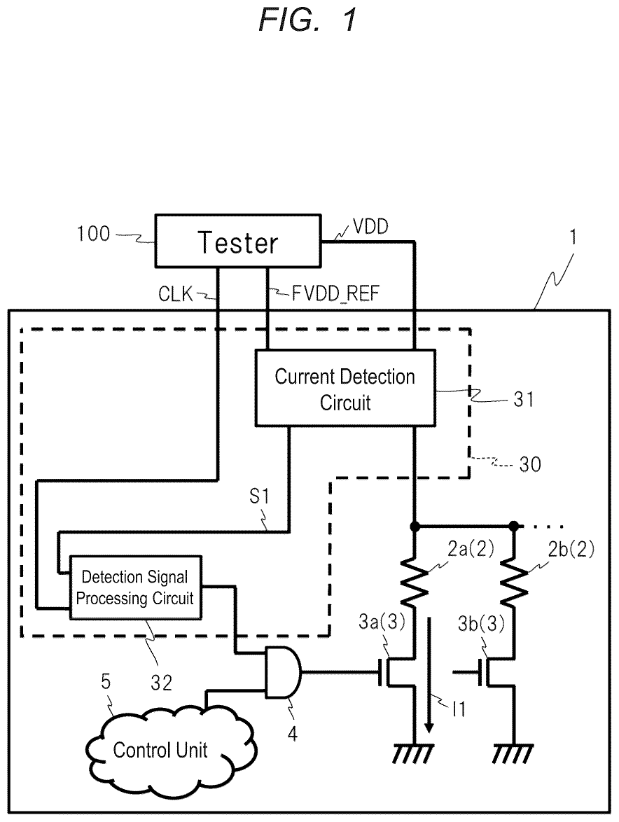

FIG. 1 shows a schematic diagram of the circuit configuration of the semiconductor device according to this embodiment. As shown in FIG. 1, the semiconductor device 1 includes an electrical fuse 2, a cutting control transistor 3, an AND circuit 4, a control unit 5, and a current control circuit 30.

Electrical fuse 2 has one terminal (first terminal) electrically connected to the current control circuit 30, and the other terminal (second terminal) electrically connected to the drain terminal of the cutting control transistor 3. In FIG. 1, two electrical fuses 2a and 2b are shown as the electrical fuse 2, but three or more may be connected.

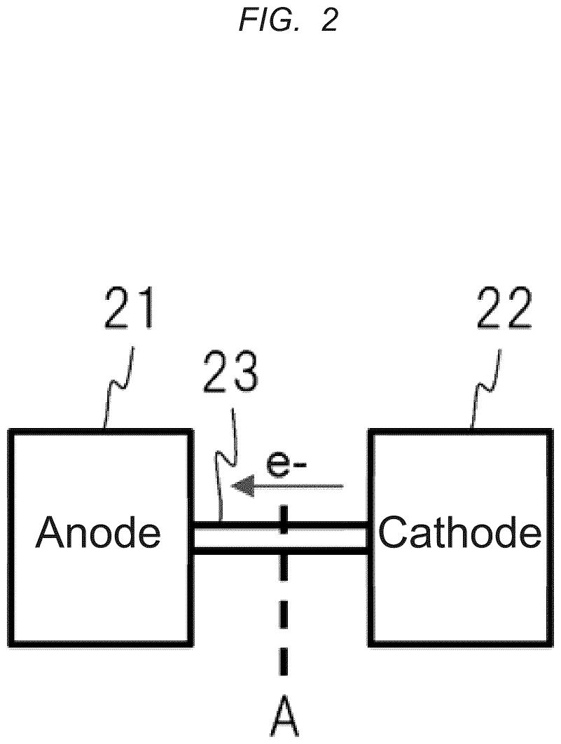

The cutting control transistor 3 is composed of an nMOS transistor in FIG. 2. The cutting control transistor 3 has its drain terminal electrically connected to the other terminal of the electrical fuse 2, and a ground voltage is supplied to its source terminal. In other words, the cutting control transistor 3 functions as a first transistor connected in series between the other terminal of the electrical fuse 2 and the ground potential. This cutting control transistor 3 switches whether or not to allow current to flow through the electrical fuse 2, as described later. In this embodiment, the cutting control transistor 3 is composed of an nMOS transistor, but it may be composed of a pMOS transistor.

Additionally, the gate terminal of the cutting control transistor 3 is electrically connected to the output terminal of the AND circuit 4. In FIG. 1, two cutting control transistors, 3a and 3b, are shown as the cutting control transistor 3, but more than three may be connected in accordance with the electric fuse 2.

The AND circuit 4 has one input terminal electrically connected to the detection signal processing circuit 32, which will be described later, and the other input terminal electrically connected to the control unit 5. The output terminal of the AND circuit 4 is connected to the gate terminal of the cutting control transistor 3. In FIG. 1, only the AND circuit 4 connected to the cutting control transistor 3a is described, but in practice, a plurality of AND circuits are provided for each cutting control transistor 3. In other words, each AND circuit 4 controls whether to cut the corresponding electric fuses 2a, 2b for each cutting control transistor 3a, 3b. The AND circuit 4 outputs the logical product of the output signal (control signal) from the detection signal processing circuit 32, which will be described later, and the output signal from the control unit 5. That is, the AND circuit 4 functions as a control circuit for performing switching control of the first transistor based on the control signal from the detection signal processing circuit 32.

Control unit 5 has its output terminal connected to the other input terminal of the AND circuit 4. Control unit 5 is a circuit that selects, for example, one electric fuse 2 to be cut and outputs a selection signal to the AND circuit 4 corresponding to the selected electric fuse 2.

The current control circuit 30 includes a current detection circuit 31 and a detection signal processing circuit 32. The current detection circuit 31 is electrically connected to one terminal of electric fuse 2. Additionally, the current detection circuit 31 is applied with a cutting high voltage VDD from a tester 100 provided outside the semiconductor device 1.

For the cutting high voltage VDD, for example, 7.5V is applied. Furthermore, the current detection circuit 31 receives a current reference voltage FVDD_REF from the tester 100. The current reference voltage FVDD_REF is a reference voltage (second voltage) for detecting a low current, which will be described later. Then, the current detection circuit 31 outputs a low current detection signal S1 to the detection signal processing circuit 32 when a low current is detected.

The detection signal processing circuit 32 is electrically connected to the current detection circuit 31. The detection signal processing circuit 32 receives the low current detection signal S1 from the current detection circuit 31. Additionally, the detection signal processing circuit 32 receives a cutting clock signal CLK from the tester 100. The detection signal processing circuit 32 outputs a control signal to the above mentioned AND circuit 4 based on the low current detection signal S1 and the cutting clock signal CLK.

The AND circuit 4, which has received the control signal, turns on the cutting control transistor 3. Then, the cutting current I1 based on the cutting high voltage VDD applied from the tester 100 flows s through the electric fuse 2, and the electric fuse 2 is melted by the cutting current I1.

### Supplement to the Problem

Here, the cutting failure of electric fuse 2 formed in the semiconductor device 1 will be described with reference to FIGS. 2 to 6. FIG. 2 is a view of electric fuse 2 formed in semiconductor device 1 as seen from above the chip. As shown in FIG. 2, electric fuse 2 includes an anode 21, a cathode 22, and a fuse body 23.

The anode 21 corresponds to the above mentioned one terminal, and a voltage is applied through the current detection circuit 31. The cathode 22 corresponds to the above mentioned other terminal and is grounded through the cutting control transistor 3. Fuse body 23 is provided between anode 21 and cathode 22 and becomes the part (cutting region) that is melted by the current accompanying the applied voltage.

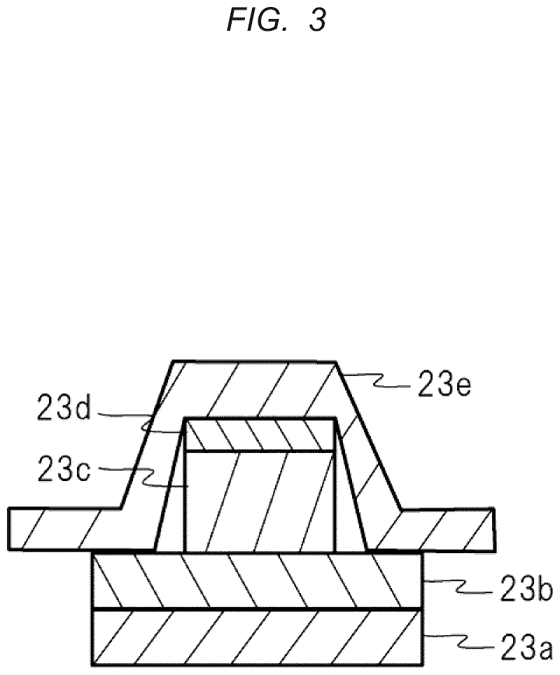

FIG. 3 shows a cross-sectional view along line A of FIG. 2. The substrate on which the fuse body 23 is formed has an STI (Shallow Trench Isolation) region 23b formed on HVNW (High Voltage N-Well) 23a. The fuse body 23 is formed in a wiring shape by a polysilicon film 23c formed on the STI region 23b and a metal silicide film 23d such as a cobalt silicide film (CoSi) formed on the polysilicon film 23c. Additionally, a silicon nitride film (SiN) 23e is formed on the upper layer of the fuse body 23 to cover the polysilicon film 23c and the metal silicide film 23d.

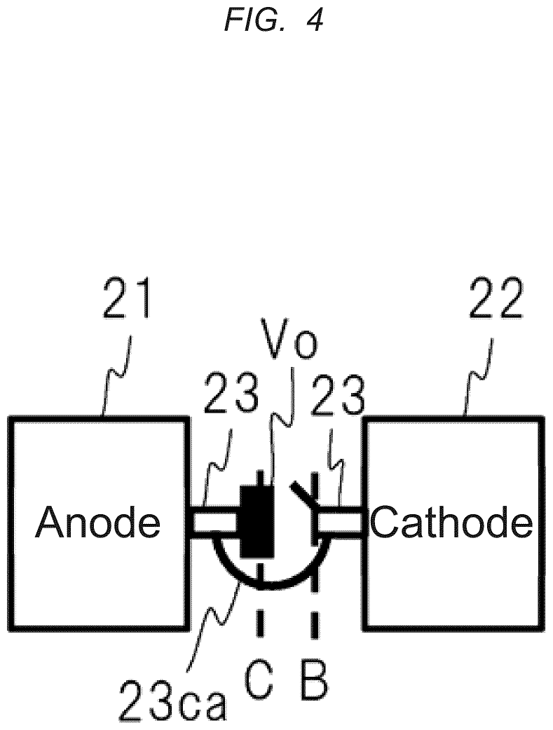

FIG. 4 is a view of the cutting failure state of electric fuse 2 shown in FIG. 2 as seen from above the wafer. As shown in FIG. 4, the fuse body 23 is melted by the current flowing from anode 21 to cathode 22, and a void (Void) Vo is formed on the anode 21 side of the cut fuse body 23. However, the melted polysilicon extends from the cathode 22 side of the cut fuse body 23, conducting with the anode 21 side. This is thought to be caused by the fact that the melting point of the silicon nitride film 23e is low, and when the fuse body 23 is melted, the melted region of this silicon nitride film 23e becomes a path for the melted polysilicon.

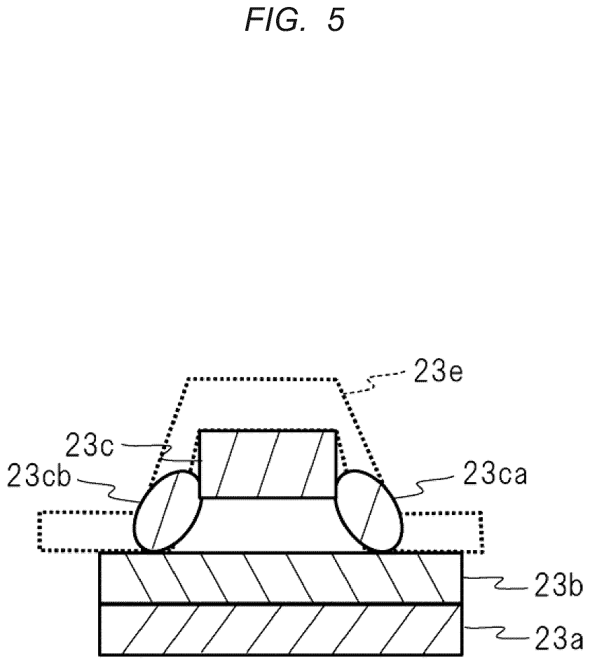

FIG. 5 shows a cross-sectional view along line B of FIG. 4. FIG. 4 shows cathode 22 side of the cut fuse body 23 described above. As described above, extensions 23ca, 23cb are formed in the portion where the silicon nitride film 23e was formed from the polysilicon film 23c.

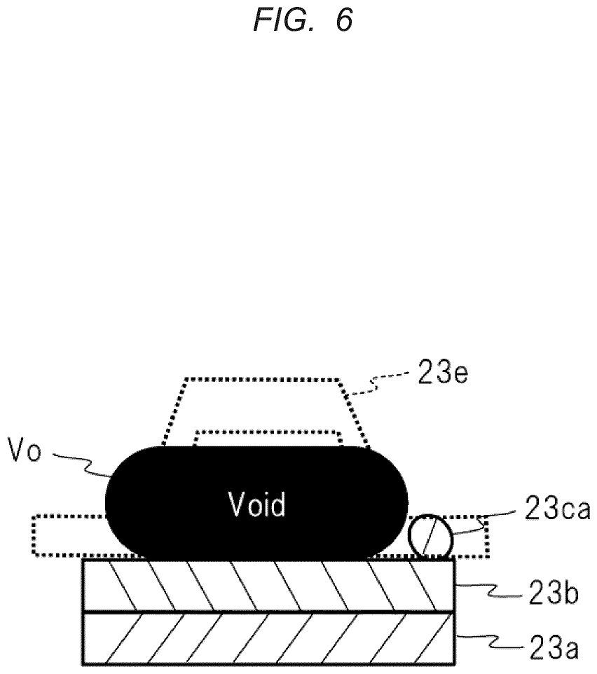

FIG. 6 shows a cross-sectional view along line C of FIG. 4. FIG. 6 shows the anode 21 side of the cut fuse body 23 described above. The above mentioned extension 23ca extends so as to avoid the void Vo. And this extension 23ca is conducting to the anode 21 side of the fuse body 23 as shown in FIG. 4.

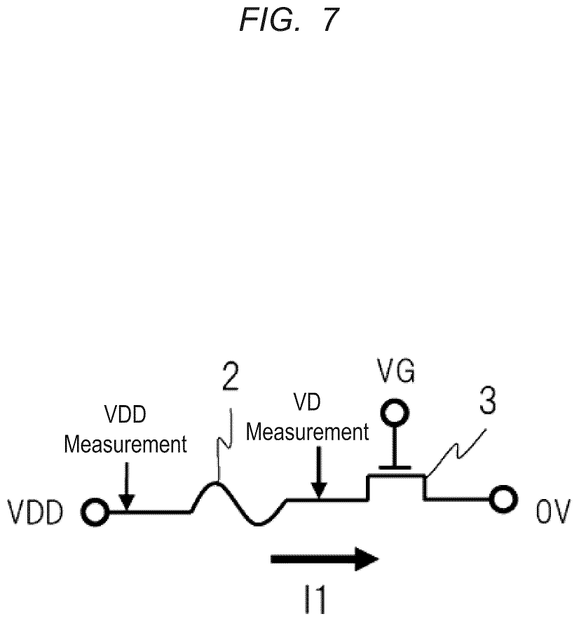

Next, the current application time during cutting of electric fuse 2 will be described with reference to FIGS. 7 to 11. FIG. 7 is a circuit diagram showing the electric fuse 2 and the cutting control transistor 3.

VDD in FIG. 7 indicates the cutting high voltage VDD. VDD measurement indicates measuring the potential on one terminal side of the electric fuse 2. VD measurement indicates measuring the potential on the other terminal side of the electric fuse 2. VG indicates the gate terminal of the cutting control transistor 3. I1 is the above mentioned cutting current I1.

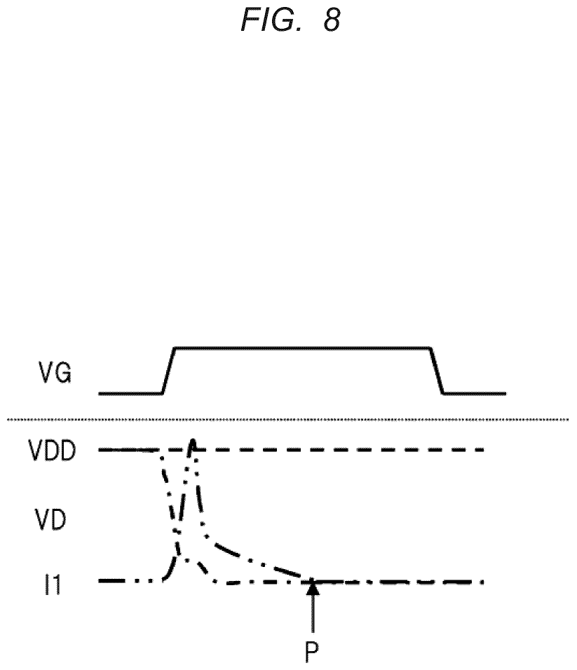

FIG. 8 shows an example of changes in the cutting high voltage VDD, VD, and cutting current I1 in the circuit of FIG. 7. In FIG. 8, the dashed line indicates the cutting high voltage VDD, the dash-dot line indicates VD, and the double-dot line indicates I1.

In FIG. 8, VG is the voltage applied to the gate terminal of the cutting control transistor 3. When the gate voltage VG is applied (high level), the cutting control transistor 3 turns on. Then, the cutting current I1 begins to flow, and VD starts to decrease. Then, VD becomes 0V after the cutting current I1 exceeds its peak, but the cutting current I1 continues to flow while decreasing, reaching 0 mA. Then, after the cutting current I1 becomes 0 mA, the gate voltage VG is stopped (low level). For this reason, the gate voltage VG was applied excessively, causing a large amount of the polysilicon film 23c to melt, making it easy for the extension 23ca to form.

As shown in FIG. 8, after the peak of the cutting current I1, VD changes to approximately 0V due to the melting of the polysilicon film 23c, but at this timing, the cutting current I1 is still flowing, and complete melting has not been achieved. The timing when the cutting current I1 becomes approximately 0 mA is the timing when the fuse body 23 is completely melted. However, even just before the cutting current I1 becomes approximately 0 mA, it is possible to melt the polysilicon film 23c with the residual heat in the electric fuse 2.

Therefore, in this embodiment, the cutting control transistor 3 is turned off just before the cutting current I1 becomes approximately 0 mA. The circuit shown in FIG. 1 has a function to detect a preset current value of the cutting current I1 and autonomously turn off the cutting control transistor 3. Detailed operation will be described later.

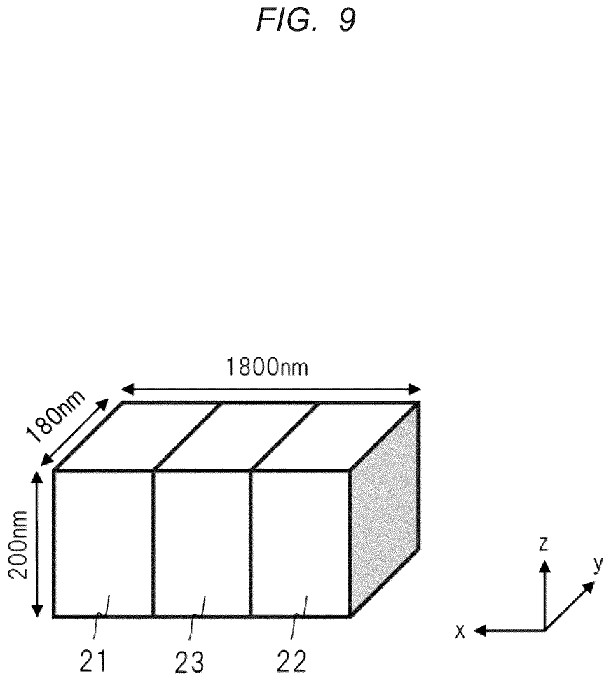

Here, the possibility of melting the polysilicon film 23c with the residual heat in the electric fuse 2 will be described with reference to FIGS. 9 to 11. FIG. 9 schematically shows electric fuse 2 as a rectangular prism. In FIG. 9, anode 21, fuse body 23, and cathode 22 are arranged in order from left to right. And the anode 21, fuse body 23, and cathode 22 are all rectangular prisms with an x-direction length of 600 nm, a y-direction length of 180 nm, and a z-direction length of 200 nm. Also, the cutting high voltage VDD is set to 8V.

To melt the polysilicon film 23c of the fuse body 23 of the size shown in FIG. 9, assuming a sheet resistance of 17.1 [Ω/□], a heat amount of 10.5×10−9 [J] is required. Also, since the current required for cutting is very large, assuming a terminal potential difference of 6.0V, a current peak of about 35 mA is required, assuming a peak time of 50 ns.

$$Current I = 35 mA ( = 6 V / 171 Ω )$$

$$Heat amount = 10.5 [ nJ ] ( = 6 V \times 35 mA \times 50 ns )$$

Of the 10.5 nJ, a part is dissipated to the electrodes at both ends (anode 21, cathode 22), and the remaining heat melts the 600 nm (x-direction) region.

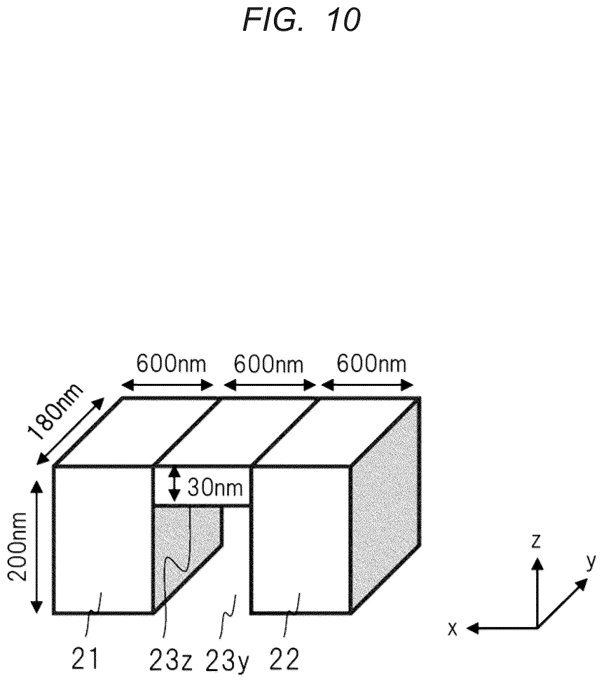

The region that can be melted with the above mentioned heat amount is 600 nm×180 nm×170 nm, and a remaining region 23z of 600 nm×180 nm×approximately 30 nm is generated (FIG. 10). In FIG. 10, the melted portion (first portion) is indicated by reference numeral 23y.

Resistance: 171Ω×2/3+171Ω×200 nm/30 nm×1/3=494Ω

$$Current I = 16.2 mA ( = 8 V / 494 Ω )$$

$$Heat = 9.7 [ nJ ] ( = 8 V \times 16.2 mA \times 150 ns / 2 )$$

Most of the 9.7 nJ of heat generated by the 16.2 mA current occurs in the remaining region 23z of 30 nm (Z direction), melting the remaining region 23z with that heat.

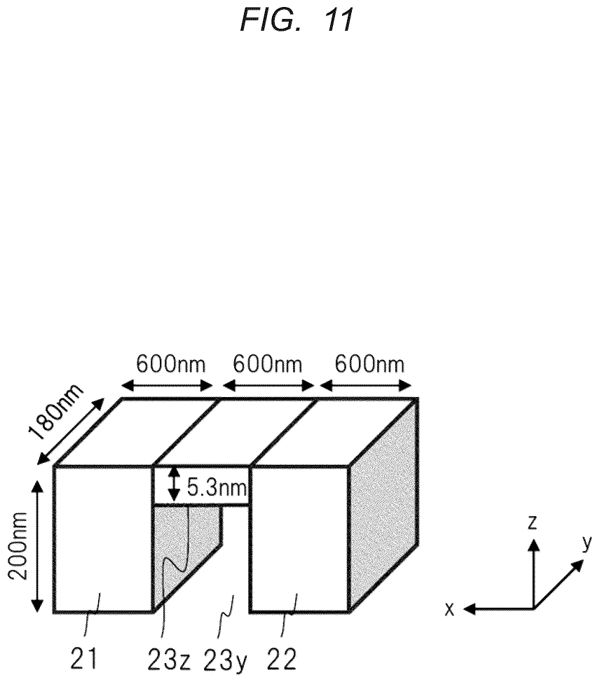

From the evaluation trends by the inventors so far, it has been found that even if the application of the gate voltage VG is interrupted to stop the current, the maximum limit that can be cut by residual heat is 5.3 nm (Z direction) (FIG. 11).

Resistance: 171Ω×2/3+171Ω×200 nm/5.3 nm×1/3=2265Ω

$$Current I = 3.5 mA ( = 8 V / 2265 Ω )$$

In other words, if it is 5.3 nm or less, it can be cut by residual heat, so it is preferable that the cutting current I1 is 3.5 mA or less. That is, it is preferable that the cutting current I1 is less than or equal to the current value calculated from the upper limit of the polysilicon wiring film thickness that can be completely melted by residual heat.

In this way, the timing when the cutting current I1 becomes, for example, 3.5 mA or less is detected, and at that timing, the application of the gate voltage VG is interrupted to stop the cutting current I1. Thereafter, the remaining region 23z can be melted by residual heat. Therefore, the gate voltage VG is not applied more than necessary, and the occurrence of the extension portion 23ca can be suppressed.

Circuit of this Embodiment

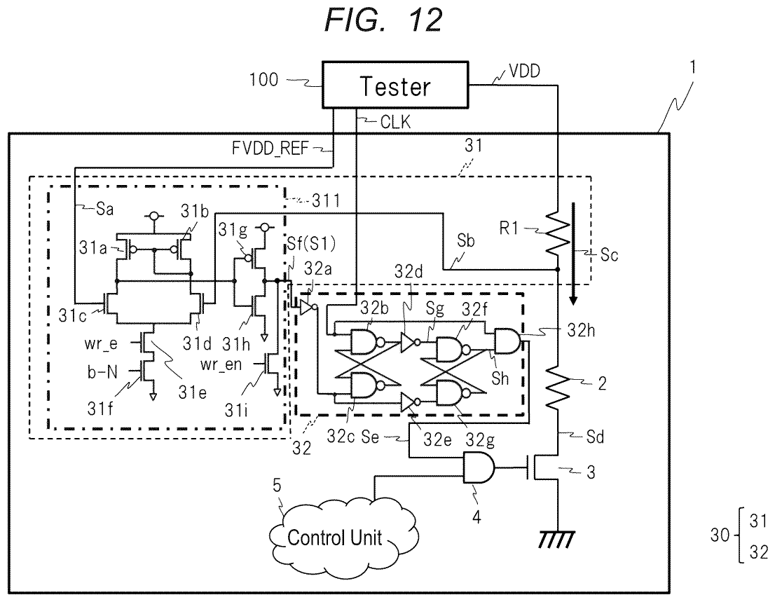

FIG. 12 shows a detailed circuit diagram of the semiconductor device 1 shown in FIG. 1. FIG. 12 shows the detailed circuit of the current control circuit 30 (current detection circuit 31, detection signal processing circuit 32) shown in FIG. 1. Also, in FIG. 12, for convenience of description, only one of the electric fuses 2 and the cutting control transistor 3 is shown.

The current detection circuit 31 includes a resistor R1 and a sense circuit 311. The resistor R1 is a resistance element with one terminal electrically connected to the tester 100 and a cutting high voltage VDD applied. The other terminal of the resistor R1 is electrically connected to one terminal of the electric fuse 2. Also, the other terminal of the resistor R1 is electrically connected to the sense circuit 311. The resistor R1 has a resistance value that does not inhibit the cutting of the electric fuse 2.

The sense circuit 311 includes pMOS transistors 31a and 31b, nMOS transistors 31c, 31d, 31e, 31f, 31h, and 31i, and a pMOS transistor 31g.

The source terminal of the pMOS transistor 31a is electrically connected to the power supply. The drain terminal of the pMOS transistor 31a is electrically connected to the drain terminal of the nMOS transistor 31c, the gate terminal of the pMOS transistor 31g, and the gate terminal of the nMOS transistor 31h. Also, the gate terminal of the pMOS transistor 31a is electrically connected to the gate terminal of the pMOS transistor 31b, the drain terminal, and the drain terminal of the nMOS transistor 31d.

The source terminal of the pMOS transistor 31b is electrically connected to the power supply.

The source terminal of the nMOS transistor 31c is electrically connected to the source terminal of the nMOS transistor 31d and the drain terminal of the nMOS transistor 31e. Also, the gate terminal of the nMOS transistor 31c is electrically connected to the tester 100, and the current reference voltage FVDD_REF is input.

The gate terminal of the nMOS transistor 31d is electrically connected to the other terminal of the resistor R1.

The source terminal of the nMOS transistor 31e is electrically connected to the drain terminal of the nMOS transistor 31f. Also, the write enable signal wr_e is input to the gate terminal of the nMOS transistor 31e.

The source terminal of the nMOS transistor 31f is supplied with a ground voltage. Also, the bias signal b-N is input to the gate terminal of the nMOS transistor 31f.

The source terminal of the pMOS transistor 31g is electrically connected to the power supply. Also, the drain terminal of the pMOS transistor 31g is electrically connected to the drain terminal of the nMOS transistor 31h, the drain terminal of the nMOS transistor 31i, and the detection signal processing circuit 32.

The source terminal of the nMOS transistor 31h is supplied with a ground voltage.

The source terminal of the nMOS transistor 31i is supplied with a ground voltage. Also, the write enable n signal wr_en is input to the gate terminal of the nMOS transistor 311. The write enable n signal wr_en is the inverted signal of the write enable signal wr_e.

The sense circuit 311 compares the current reference voltage FVDD REF input to the gate terminal of the nMOS transistor 31c with the potential of the other terminal of the resistor R1 input to the gate terminal of the nMOS transistor 31d, and when the potential of the other terminal of the resistor R1 becomes equal to or less than the current reference voltage FVDD REF, the low current detection signal S1 output to the detection signal processing circuit 32 becomes high level. Here, the current reference voltage FVDD_REF is a voltage value for detecting a current value (low current value) that can melt the remaining region of the polysilicon film 23c with residual heat such as 3.5 mA described in FIGS. 9 to 11 and is a voltage value lower than the cutting high voltage VDD. The current reference voltage FVDD_REF becomes a voltage value smaller by the voltage drop that occurs when the low current value described above flows through the resistor R1 with respect to the cutting high voltage VDD.

The detection signal processing circuit 32 includes an inverter circuit 32a, NAND circuits 32b and 32c, inverter circuits 32d and 32e, NAND circuits 32f and 32g, and an AND circuit 32h.

The output of the current detection circuit 31 (sense circuit 311) is electrically connected to the input terminal of the inverter circuit 32a. The output terminal of the inverter circuit 32a is electrically connected to the second input terminal of the NAND circuit 32c and the input terminal of the inverter circuit 32e.

The tester 100 is electrically connected to the first input terminal of the NAND circuit 32b, and the cutting clock signal CLK is input. The output terminal of the NAND circuit 32c is electrically connected to the second input terminal of the NAND circuit 32b. The output terminal of the NAND circuit 32b is electrically connected to the input terminal of the inverter circuit 32d and the first input terminal of the NAND circuit 32c.

The output terminal of the inverter circuit 32d is electrically connected to the first input terminal of the NAND circuit 32f.

The output terminal of the inverter circuit 32e is electrically connected to the second input terminal of the NAND circuit 32g.

The output terminal of the NAND circuit 32g is electrically connected to the second input terminal of the NAND circuit 32f. The output terminal of the NAND circuit 32f is electrically connected to the second input terminal of the AND circuit 32h and the first input terminal of the NAND circuit 32g.

The tester 100 is electrically connected to the first input terminal of the AND circuit 32h, and the cutting clock signal CLK is input. The output terminal of the AND circuit 32h is electrically connected to the first input terminal of the AND circuit 4.

The detection signal processing circuit 32 forms a latch circuit with the NAND circuits 32b and 32c and forms a latch circuit with the NAND circuits 32f and 32g. In other words, the detection signal processing circuit 32 has a double NAND latch circuit configuration.

Here, since the current detection circuit 31 needs to detect with the cutting high voltage VDD, the power supply is operated with the cutting high voltage VDD. The detection signal processing circuit 32 is a logic signal processing, so it is operated with the same power supply as the control unit 5.

Also, the signal output from the current detection circuit 31 to the detection signal processing circuit 32 is a signal across the power supply and becomes a signal from high voltage to low voltage. Therefore, a circuit consisting of the nMOS transistor 31i is provided at the output of the current detection circuit, so that the output of the current detection circuit 31 can be fixed at a low level. This circuit consisting of the nMOS transistor 31i is input with the write enable n signal wr_en, which is the inverted signal of the write enable signal wr_e. Therefore, even when the cutting high voltage VDD becomes 0V, such as when the electric fuse 2 is not being cut, the output of the current detection circuit 31 can be fixed.

The detailed circuits of the current detection circuit 31 and the detection signal processing circuit 32 described above are examples, and other types of circuits may be used as long as they operate in the same manner as described above, and the definition of positive and negative logic in the logic circuit is also arbitrary.

Operation of the Circuit of this Embodiment

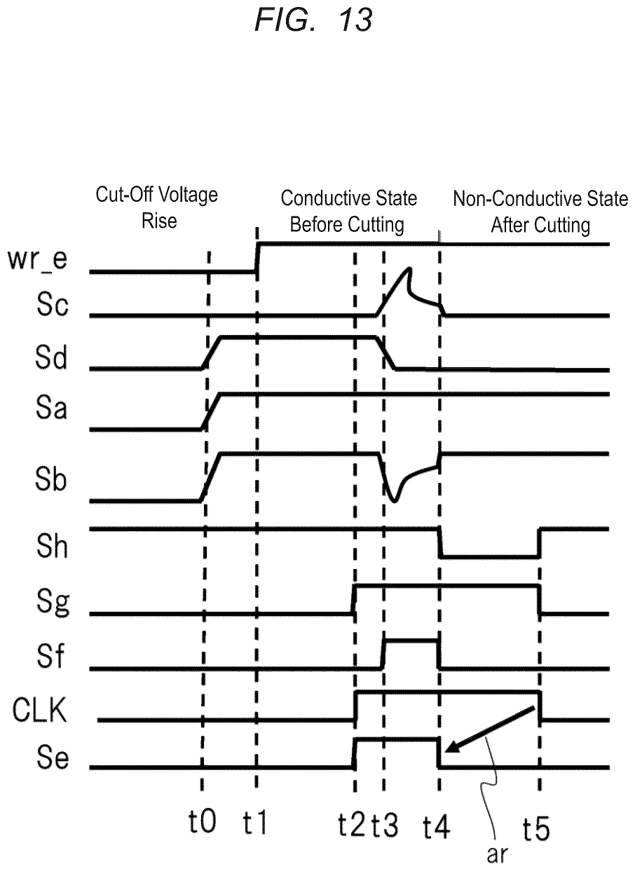

Next, the operation of the current control circuit 30 (current detection circuit 31, detection signal processing circuit 32) having the above-described configuration will be described with reference to the timing chart of FIG. 13. Sc in the timing chart of FIG. 13 shows the cutting current I1 flowing from the resistor R1 in FIG. 12 to the electric fuse 2. Sd shows the change in potential at the other terminal of the electric fuse 2. Sa shows the current reference voltage FVDD_REF. Sb shows the potential of the other terminal of the resistor R1. Sh shows the output signal of the NAND circuit 32f. Sg indicates the output signal of the inverter circuit 32d. Sf indicates the output signal of the current detection circuit 31. Se indicates the output signal of the detection signal processing circuit 32.

First, as the cut-off voltage rises, at time to, the application of the high voltage VDD for cutting is started from the tester 100, and the reference voltage FVDD REF for current is output. Then, the voltages of Sb and Sd begin to rise. Next, at time t1, the write enable signal wr_e is set to high level to start cutting. At this time, the bias signal b-N is also set to a high level.

Next, at time t2, the clock signal CLK for cutting is input from the tester 100 (rises to high level). Then, Sg and Se become high level. This Sg is a write (cut) start signal generated by the first stage latch (NAND circuit 32b, NAND circuit 32c) of the detection signal processing circuit 32. Also, Se is the control signal mentioned above. At time t2, if the selection signal is output from the control unit 5 to the AND circuit 4, the output of the AND circuit 4 becomes high level due to the output of the control signal Se, and the cut-off control transistor 3 turns on. When the cut-off control transistor 3 turns on, the cut-off current I1 (Sc) begins to flow through the electric fuse 2.

As the cut-off current I1 (Sc) begins to flow, the potentials of Sd and Sb also start to decrease. Then, at time t3, when the potential of Sb becomes equal to or less than Sa (reference voltage FVDD REF for current), the low current detection signal S1, which is Sf, becomes high level. Sb detects the voltage drop due to the cut-off current I1 (Sc) across the resistor R1, and when this voltage drop becomes equal to or less than the reference voltage FVDD_REF for current, the low current detection signal S1 (Sf) becomes high level.

After time t3, the cut-off current I1 (Sc) passes its peak (first current value) and begins to decrease. This indicates that the melting of the fuse body 23 is progressing, and the wiring (polysilicon) which is the fuse body 23 is beginning to cut.

Then, at time t4, when the voltage of Sb exceeds Sa, Sf and Sh become low level. In other words, it indicates that a current (e.g., 3.5 mA) that determines a low current state due to the voltage drop across the resistor RI has been detected. That is, the current detection circuit 31 outputs the low current detection signal S1 (Sf: detection signal) to the detection signal processing circuit 32. Sh is a write (cut) end signal generated by the second stage latch (NAND circuit 32f, NAND circuit 32g) of the detection signal processing circuit 32. Since Sh becomes low level, Se (control signal), which is the output of the AND circuit 32h, becomes low level. When Se becomes low level, the AND circuit 4 becomes low level, and the cut-off control transistor 3 turns OFF. Therefore, the current flowing through the fuse body 23 stops (ends). Thereafter, melting due to residual heat is performed as described above.

Then, at time t5, the clock signal CLK for cutting falls to low level. Then, Sg becomes low level and Sh becomes high level.

By operating as described above, it becomes possible to turn off the cut-off control transistor 3 when the electric fuse 2 is in a super high resistance state and the cut-off current I1 is almost not flowing. Therefore, as shown by the arrow ar in FIG. 13, the application time of Se (gate voltage of the cut-off control transistor 3) can be shortened. Also, by detecting the cut-off current I1, the length of the on period of the cut-off control transistor 3 can be autonomously adjusted. Therefore, it is possible to optimally cut the electric fuse 2 while using the clock signal CLK for cutting output from the conventional tester 100.

Also, the application of the gate voltage of the cut-off control transistor 3 is determined by the voltage drop across the resistor R1. Therefore, even if there is process variation, the effective period of gate voltage application can be autonomously adjusted according to the variation. Therefore, it is possible to improve the yield of the product.

### Second Embodiment

Next, the second embodiment will be described. In the following, descriptions of parts that overlap with the above mentioned embodiment will be omitted in principle.

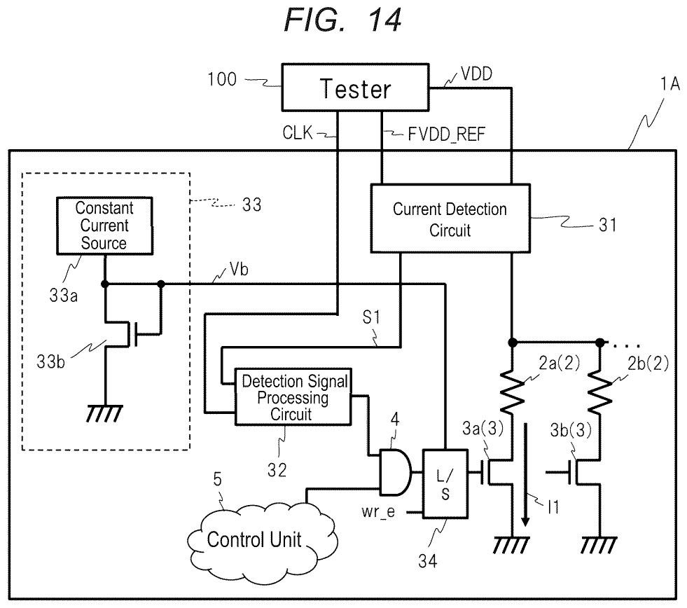

FIG. 14 shows a schematic diagram of the circuit configuration of the semiconductor device according to this embodiment. As shown in FIG. 14, the semiconductor device 1A includes, in addition to the configuration shown in FIG. 1, a bias voltage generation unit 33 and a level shift circuit (L/S) 34.

Problems in this Embodiment

As described in the first embodiment, the cutting failure of the electric fuse 2 is caused by the large amount of melted polysilicon during cutting. Here, in the MOS transistor for current control, the increase in peak current during cutting due to the influence of threshold voltage Vth variation is also considered a factor. When the peak current during cutting increases, the amount of melted polysilicon increases, raising the possibility of conduction through the extension part 23ca.

Therefore, in this embodiment, a circuit is added to generate the peak current during cutting as a bias current in the internal circuit, thereby suppressing excessive peak current.

Circuit Configuration in this Embodiment

The bias voltage generation unit 33 shown in FIG. 14 includes a constant current source 33a and an nMOS transistor 33b. The constant current source 33a is a current source matched to the peak current value flowing through the electric fuse 2, such as 35 mA.

The nMOS transistor 33b is a replica having the same size and characteristics as the cut-off control transistor 3. That is, the nMOS transistor 33b functions as a second transistor having the same characteristics as the first transistor. The drain terminal of the nMOS transistor 33b is electrically connected to the constant current source 33a, the gate terminal of the nMOS transistor 33b, and the level shift circuit 34. The source terminal of the nMOS transistor 33b is supplied with a ground voltage. The bias voltage generation unit 33 supplies the drain voltage of the nMOS transistor 33b as the bias voltage Vb to the level shift circuit 34.

The level shift circuit 34 includes three input terminals and one output terminal. The output terminal of the AND circuit 4 is electrically connected to the first input terminal of level shift circuit 34. The write enable signal wr_e is input to the second input terminal of the level shift circuit 34. The bias voltage generation unit 33 is electrically connected to the third input terminal of the level shift circuit 34, and the bias voltage Vb is input.

level shift circuit 34 applies the bias voltage Vb as the gate voltage of the cut-off control transistor 3 when the write enable signal wr_e is high level and the output of the AND circuit 4 is high level. By applying the bias voltage Vb as the gate voltage to the cut-off control transistor 3, the drain current (cut-off current I1) of the cut-off control transistor 3 can be limited to a value corresponding to the bias voltage Vb.

According to the configuration of this embodiment, the amount of melted polysilicon can be suppressed by reducing the peak current during the cutting of the electric fuse 2. Therefore, it is possible to suppress the cutting failure of the electric fuse 2 due to the threshold voltage Vth variation of the MOS transistor.

### Third Embodiment

Next, the third embodiment will be described. In the following, descriptions of parts that overlap with the above mentioned embodiment will be omitted in principle.

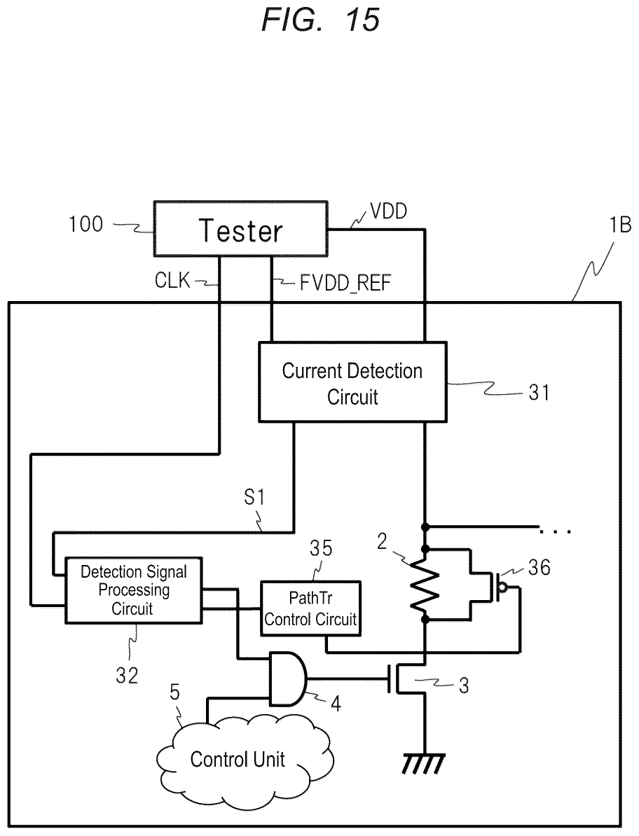

FIG. 15 shows a schematic diagram of the circuit configuration of the semiconductor device according to this embodiment. As shown in FIG. 15, the semiconductor device 1B includes, in addition to the configuration shown in FIG. 1, a PathTr control circuit 35 and a PathTr 36.

Problems in this Embodiment

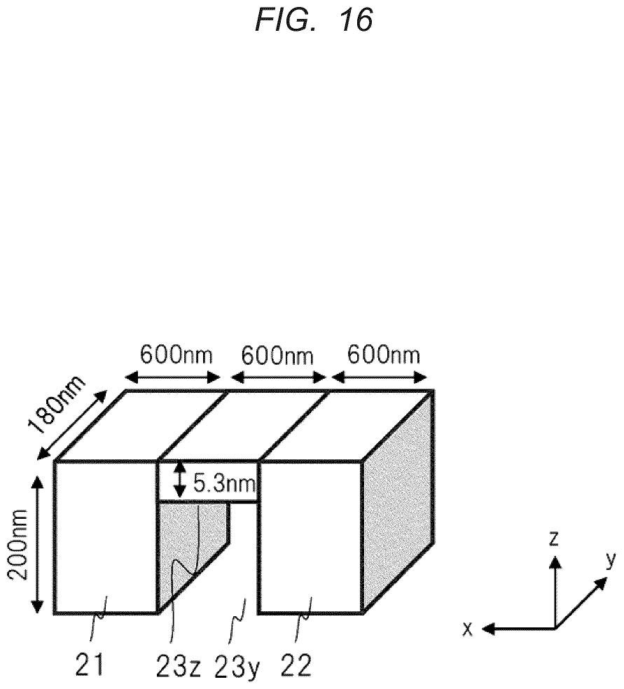

FIG. 16 is a reprint of FIG. 11. As shown in FIG. 16, just before the cut-off control transistor 3 turns off, due to the movement of charge by the unmelted part (remaining region 23z) and the delay of the current control circuit 30, the anode 21 side becomes 0V or a near intermediate potential when the cut-off control transistor 3 is off.

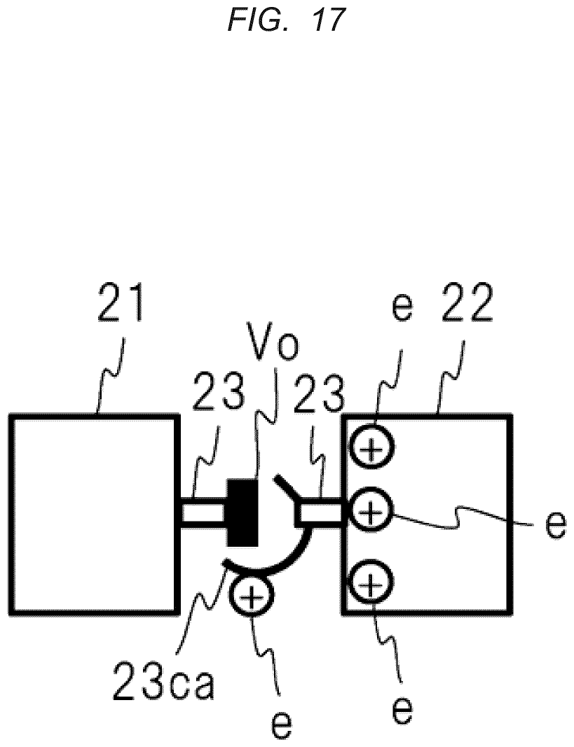

Therefore, the anode 21 is at 0V (or intermediate potential), and the cathode 22 is in a state where the high voltage VDD for cutting is applied. As shown in FIG. 17, if there is residual charge e in the melted polysilicon of the extension part 23ca at this time, the melted polysilicon is in a state where it is easy to move due to the attraction of the high voltage VDD for cutting that has been continuously applied since before cutting. Therefore, in order to further reduce defects, it is also important to eliminate (or reduce) the potential difference between the terminals of the electric fuse 2 after cutting.

Circuit of this Embodiment

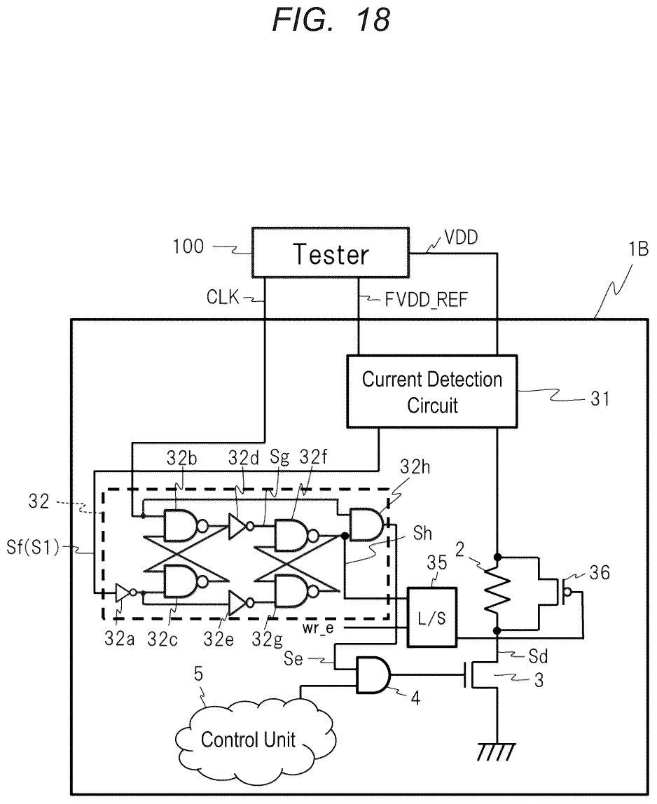

FIG. 18 shows a detailed circuit diagram of the semiconductor device 1B shown in FIG. 15. In FIG. 18, the detailed circuits of the detection signal processing circuit 32 and the PathTr control circuit 35 shown in FIG. 15 are shown. The circuit of the detection signal processing circuit 32 shown in FIG. 18 is the same as that in FIG. 12, so detailed description is omitted. In FIG. 18, the output of the NAND circuit 32f is electrically connected to the first input terminal of the level shift circuit constituting the PathTr control circuit 35.

The PathTr control circuit 35 is configured as a level shift circuit, as described above. The first input terminal of the level shift circuit receives the output of the NAND circuit 32f of the detection signal processing circuit 32. The second input terminal of the level shift circuit receives the write enable signal wr e. The output terminal of the level shift circuit is electrically connected to the gate terminal of PathTr 36. The PathTr control circuit 35 controls the gate voltage of PathTr 36.

PathTr36 is composed of a pMOS transistor. PathTr36 has its source terminal electrically connected to one terminal of the electric fuse 2 (on the current detection circuit 31 side). PathTr36 has its drain terminal electrically connected to the other terminal of the electric fuse 2 (on the cut-off control transistor 3 side). In other words, PathTr36 functions as a third transistor connected in parallel with the electric fuse 2. In this embodiment, PathTr36 is a pMOS transistor, but it may also be an nMOS transistor. It goes without saying that if an nMOS transistor is used, the signal level output by the PathTr control circuit 35 should also be appropriately adjusted.

Operation of the Circuit in this Embodiment

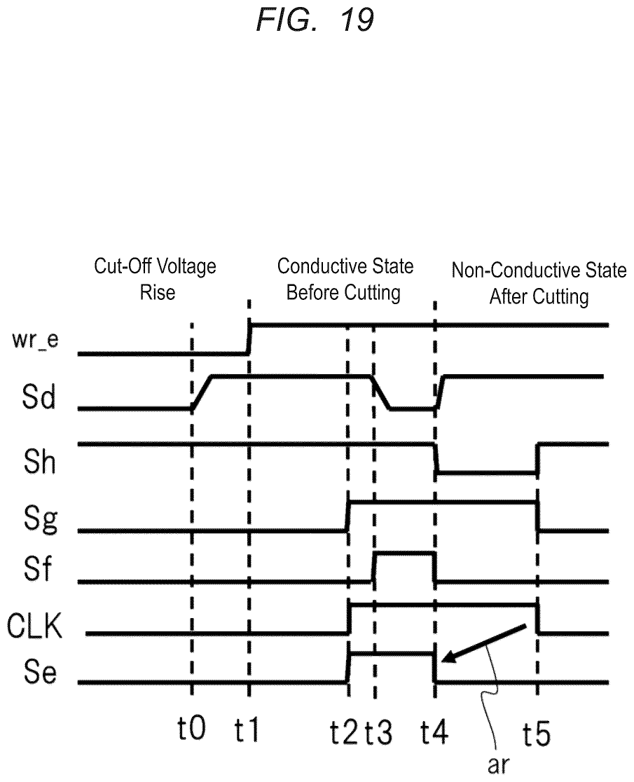

Next, the operation of the circuit with the above configuration (current detection circuit 31, detection signal processing circuit 32) will be described with reference to the timing chart in FIG. 19. The signals Sd, Sh, Sg, Sf, CLK, and Se in the timing chart of FIG. 19 are the same as the signals with the same names shown in the timing chart of FIG. 13. Also, the timing from time to time t5 is the same as in FIG. 13.

In FIG. 19, Sh (write end signal) becomes low level between time t4 and time t5. Sh is input to the PathTr control circuit 35 and is a signal that substantially controls PathTr36. The PathTr control circuit 35 converts the low voltage level Sh into a high voltage VDD level signal for cutting and outputs it to PathTr36. Therefore, PathTr36 is turned on between time t4 and time t5. Also, since PathTr36 is turned on at time t4, Sd (the other terminal of the electric fuse 2) becomes high level.

Additionally, the write enable signal wr_e is input to the PathTr control circuit 35, and it is controlled so that PathTr36 is turned off except during the cutting operation, thereby not affecting the read operation after writing (cutting).

With the configuration of this embodiment, after the electric fuse 2 is cut, the potential difference across the electric fuse 2 is eliminated, allowing for the relaxation of voltage stress.

### Other Embodiments

Next, other embodiments will be described. In the following, explanations of parts that overlap with the previously described embodiment will be omitted in principle.

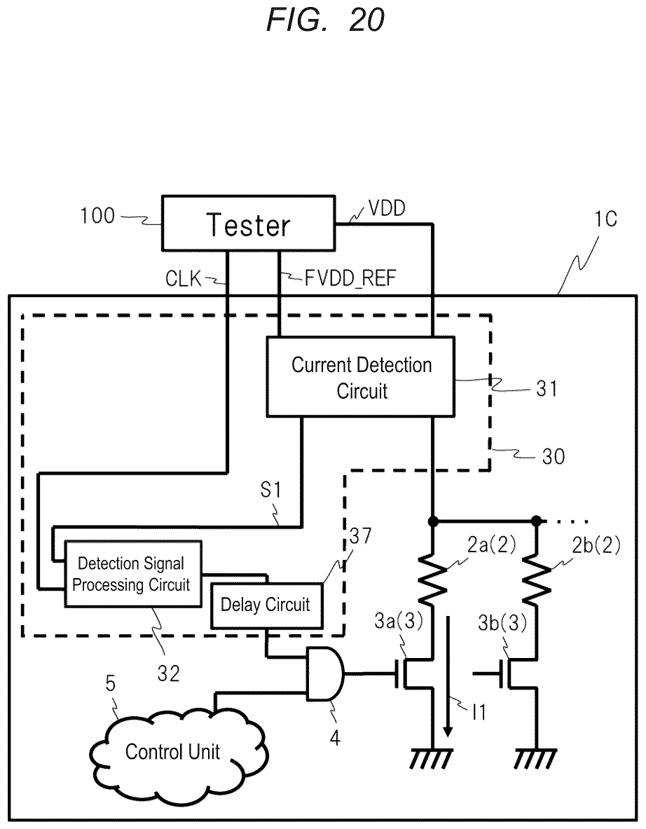

FIG. 20 shows a schematic diagram of the circuit configuration of the semiconductor device according to this embodiment. As shown in FIG. 20, the semiconductor device 1C includes a delay circuit 37 in addition to the configuration shown in FIG. 1. The delay circuit 37 delays the signal output by the detection signal processing circuit 32 by a predetermined time. Specifically, it delays the trailing edge (the part that changes from high level to low level) of the signal Se shown in FIGS. 13 and 19.

In the first embodiment, etc., 3.5 mA was exemplified as the current value at which the low current detection signal S1 is output, but if a configuration is adopted to detect even smaller currents, the difference between the current reference voltage FVDD_REF and the high voltage VDD for cutting becomes smaller. Therefore, there is a risk that the detection accuracy will be affected, causing the low current detection signal S1 to be output at a timing different from the original. Here, if the low current detection signal S1 is output earlier than the original timing, it is assumed that the fuse body 23 may not be completely melted by the residual heat, so the timing is delayed by the delay circuit 37. By doing so, it becomes possible to melt the fuse body 23 with the residual heat.

### Manufacturing Method of Semiconductor Device

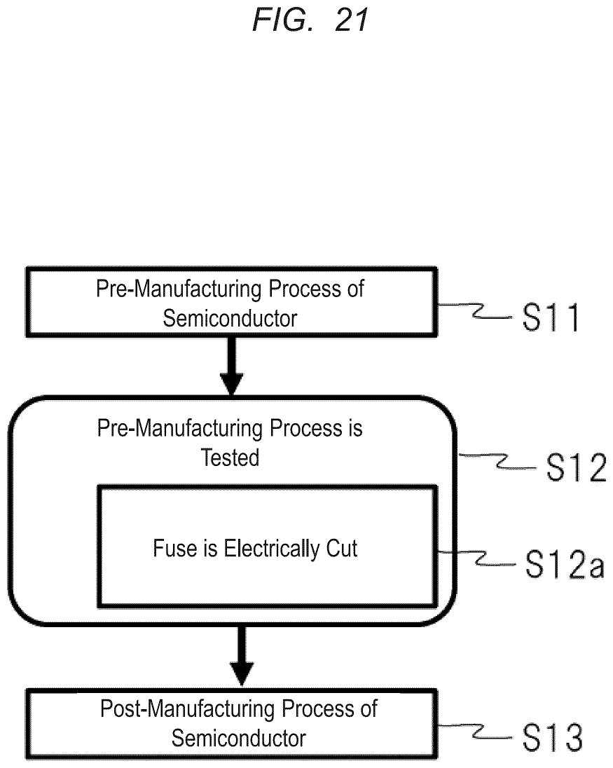

Next, the manufacturing method for producing the semiconductor device 1 described in the above embodiment will be explained with reference to FIG. 21. The following description will be given for semiconductor device 1, but it may also be the semiconductor device 1A, 1B, or 1C.

First, a semiconductor substrate is prepared, and on the surface of the region that will become the semiconductor chip (semiconductor device 1) of the semiconductor substrate, a current control circuit 30 including an electric fuse 2, a current detection circuit 31, and a detection signal processing circuit 32, a cut-off control transistor 3, an AND circuit 4, and a control unit 5 are formed. This completes the pre-manufacturing process of the semiconductor (S11).

Next, the semiconductor device 1 manufactured in the pre-manufacturing process is tested (S12). Based on the results of this test process, the conditions for the next process of cutting the electric fuse 2 are obtained. The conditions include, for example, which bit (electric fuse 2) to cut.

Next, based on the conditions obtained in S12, the electric fuse 2 is electrically cut (fused) using the high voltage VDD (first voltage) for cutting applied from an external tester 100 (S12a). This process consists of the following four steps.

First, the high voltage VDD for cutting is applied to one terminal (first terminal) of the electric fuse 2. Then, by inputting the clock signal CLK for cutting, the current control circuit 30 controls the voltage applied to the gate terminal of the cut-off control transistor 3 (first transistor) to change from a low level (first gate voltage) to a high level (second gate voltage) with respect to the AND circuit 4 (control circuit). This control switches the cut-off control transistor 3 to the on state. Then, a cutting current I1 (first current) with a first current value flows through the electric fuse 2. Therefore, the melting of fuse body 23 of electric fuse 2 is initiated using the heat generated by passing the cutting current I1 through the electric fuse 2. This is the first step.

Next, after the first step, as the melting of the fuse body 23 progresses, the current value of the cutting current I1 gradually decreases from the first current value, and the current detection circuit 31 detects a second current value that is smaller than the first current value and greater than 0 amperes. As an example, the second current value is the above mentioned 3.5 mA. This is the second step.

Next, after the second step, the current detection circuit 31 outputs a low current detection signal SI to the detection signal processing circuit 32 based on the detection of the second current value. This is the third step.

Next, after the third step, the detection signal processing circuit 32 outputs a control signal to the AND circuit 4 based on the low current detection signal S1. Then, based on the control signal, the AND circuit 4 controls the voltage applied to the gate terminal of the cut-off control transistor 3 to switch it from high level to low level, thereby switching the cut-off control transistor 3 to the off state. Then, the remaining region 23z of electric fuse 2 is cut. This is the fourth step.

After the electric fuse 2 is cut by the above four steps, the semiconductor device 1 is cut from the semiconductor substrate by a dicing process, and a post-manufacturing process is performed to obtain individual chip-shaped semiconductor devices 1 (S13).

According to the manufacturing method described above, the application of the gate voltage of the cut-off control transistor 3 is determined by the voltage drop across the resistor R1. Therefore, even if there are process variations, the effective period of gate voltage application can be automatically adjusted according to those variations. Moreover, the electric fuse 2 can be cut with high precision without individually adjusting the clock signal CLK for cutting. Therefore, the electric fuse 2 can be cut with high precision. Thus, it is possible to improve the yield of the product.

Although the invention made by the present inventor has been specifically described based on the embodiment, the present invention is not limited to the embodiment described above, and it is needless to say that various modifications can be made without departing from the gist thereof.

What is claimed is:

1. A method of manufacturing a semiconductor device with an electrical fuse, the method comprising:
(a) preparing a semiconductor substrate,
(b) forming a plurality of circuits on the surface of the region of the semiconductor substrate that becomes a semiconductor chip,
wherein the plurality of circuits include:
the electrical fuse,
a current control circuit comprising a current detection circuit electrically connected to the first terminal of the electrical fuse and a detection signal processing circuit electrically connected to the current detection circuit,
a first transistor connected in series between the second terminal of the electrical fuse and ground potential, which switches whether or not to pass current through the electrical fuse, and
a control circuit that performs switching control of the first transistor based on a control signal from the detection signal processing circuit,
(c) testing the semiconductor chip on which the plurality of circuits are formed,
(d) electrically cutting the electrical fuse using a first voltage applied externally based on the test results in the step (c), and
(e) cutting the semiconductor substrate and obtaining the semiconductor chip as the semiconductor device,
wherein the step (d) includes:
(d1) applying the first voltage to the first terminal of the electrical fuse, causing the current control circuit to switch the first transistor to the on state, passing a current of a first current value through the electrical fuse, and using the heat generated by passing the first current value through the electrical fuse to start melting the cutting region of the electrical fuse,
(d2) after the step (d1), the current detection circuit detects a second current value that is smaller than the first current value and greater than 0 amperes,
(d3) after the step (d2), the current detection circuit outputs a detection signal to the detection signal processing circuit based on detecting the second current value, and
(d4) after the step (d3), the detection signal processing circuit outputs the control signal to the control circuit based on the detection signal, and the control circuit switches the first transistor to the off state based on the control signal, performing the cutting of the electrical fuse.

2. The method of manufacturing the semiconductor device according to claim 1,
wherein the wiring forming the cutting region of the electrical fuse is made of polysilicon, and
wherein the second current value is a current value calculated to be less than or equal to the upper limit of the polysilicon wiring film thickness that can be completely melted by the residual heat in the cutting region after switching the first transistor to the off state in the step (d4).

3. The method of manufacturing the semiconductor device according to claim 1,
wherein the detection of the second current value in the step (d2) is performed by detecting the voltage drop occurring in a resistance element provided in the current detection circuit.

4. The method of manufacturing the semiconductor device according to claim 3,
wherein the detection of the second current value in the step (d2) is performed based on a second voltage input to the current detection circuit from the outside.

5. The method of manufacturing the semiconductor device according to claim 4,
wherein the first voltage and the second voltage are each a voltage supplied from a tester.

6. The method of manufacturing the semiconductor device according to claim 2,
wherein a silicon nitride film is formed on the upper layer of the polysilicon to cover it.

7. The method of manufacturing the semiconductor device according to claim 1,
wherein a bias voltage generated based on a second transistor having the same characteristics as the first transistor is applied to the gate terminal of the first transistor in the step (d).

8. The method of manufacturing the semiconductor device according to claim 1,
wherein a third transistor is connected in parallel with the electrical fuse, and
wherein the detection signal processing circuit controls the third transistor to eliminate the potential difference across the electrical fuse after the step (d4).

9. The method of manufacturing the semiconductor device according to claim 1,
wherein a delay circuit for delaying the control signal is formed as one of the plurality of circuits in the step (b), and
wherein the control signal output by the detection signal processing circuit is delayed by the delay circuit in the step (d4).

10. A semiconductor device comprising:
an electrical fuse;
a current control circuit comprising a current detection circuit electrically connected to the first terminal of the electrical fuse, and a detection signal processing circuit electrically connected to the current detection circuit;
a first transistor connected in series between the second terminal of the electrical fuse and ground potential, which switches whether or not to pass current through the electrical fuse, and
a control circuit that performs switching control of the first transistor based on a control signal from the detection signal processing circuit,
wherein the current control circuit passes a current of a first current value through the electrical fuse, using the heat generated by passing t current value through the electrical fuse to melt the cutting region of the electrical fuse,
wherein the current detection circuit detects a second current value that is smaller than the first current value and greater than 0 amperes, and outputs a detection signal to the detection signal processing circuit,
wherein the detection signal processing circuit outputs the control signal to the control circuit based on the detection signal, and
wherein the control circuit switches the first transistor to the off state based on the control signal.

11. The semiconductor device according to claim 10,
wherein a bias voltage generated based on a second transistor having the same characteristics as the first transistor is applied to the gate terminal of the first transistor.

12. The semiconductor device according to claim 10, further comprising:
a third transistor connected in parallel with the electrical fuse,
wherein the third transistor is controlled by the detection signal processing circuit.

13. The semiconductor device according to claim 10, further comprising:
a delay circuit for delaying the control signal.
